(19) United States
(12) Patent Application Publication
(10) Pub. No.: US 2005/0231197 A1
(43) Pub. Date: Oct. 20, 2005

(54) Position sensor provided in the form of a hall-effect sensor

(76) Inventors: Thomas Reininger, Wernau (DE); Stephan Schauz, Geislingen (DE); Jorg Schreier, Stuttgart (DE)

Correspondence Address: HOFFMANN & BARON, LLP, 6900 JERICHO TURNPIKE, SYOSSET, NY, 11791, US

(21) Appl. No.: 10/516,491

(22) PCT Filed: Jun. 28, 2003
(86) PCT No.: PCT/EP03/06875

§ 371 Date: Dec. 1, 2004

(30) Foreign Application Priority Data
Jul. 13, 2002 (DE) 202 11 518.6

(51) Int. Cl. G01R 33/06

(52) U.S. Cl. 324/251

(57) ABSTRACT

A position sensor designed in the form of a Hall sensor with an elongated circuit substrate (32) in the form of a molded interconnect device (MID) which includes an elongated support element consisting of injection molded plastic material, which at its front end side (37) has a support face (36), which is so fitted with a sensor element constituted by a Hall plate (27) or comprising a Hall plate (27) that the plane of the Hall plate (27) is perpendicular to the longitudinal axis of the circuit substrate (32). The sensor element (26) is electrically contacted by means of printed wiring (35), such printed wiring being constituted by a structured metal layer applied to the support element (34).

The invention relates to a position sensor in the form of a Hall sensor which is more especially provided to find a certain position of the moving output drive part of pneumatic or hydraulic linear drives.

The German patent publication (utility model) G 9,414,869 discloses a position sensor adapted to be secured in an attachment slot of a fluid power cylinder, which is based on the magnetoresistive principle. It is actuated without making physical contact by a permanent magnet moving past it which is fixed to the piston of the fluid power cylinder.

The German patent publication 19,504,608 C2 describes a position sensor having a tubular housing with a support board in it provided with an electrical circuit. At the front end of the support board a sensor element constituted by a coil is seated. The remaining cavities within the housing are filled with a duroplastic composition.

A similar, inductive position sensor is disclosed in the German patent publication 10,013,218 A1. This sensor also comprises a support board, which is fitted with an electronic circuit and at the end bears a coil which on the approach of a metallic object produces a sensor signal. The support board is for example a printed circuit board, a ceramic substrate or a flexible foil.

Known position sensors share the common feature that their dimensions are relatively large and they appear to need improvement as regards the accuracy of position detection. For instance, there is the problem of multiple switching, when the actuating element is moved past the position sensor causing the detection operation.

It is accordingly one object of the present invention to provide a position sensor with compact dimensions having a high accuracy of detection.

This object is to be attained by a position sensor designed in the form of a Hall sensor comprising an elongated circuit substrate in the form of a molded interconnect device (MID), which comprises an elongated injection molded support element manufactured of molded plastic material and having a support face at its front end side, such face so bearing a sensor element comprising a Hall plate or being constituted by a Hall plate that the plane of the Hall plate extends at a right angle to the longitudinal axis of the circuit substrate and the sensor element is electrically contacted by means of printed wiring constituted by a structured or micromachined metallic layer applied to the support element.

The production of the position sensor on the basis of an injection molded three-dimensional circuit support on an MID basis renders possible an optimum arrangement and alignment of the sensor element having a Hall plate or being formed by a Hall plate. The sensor element may for example be mounted using flip-chip technology and an anisotropic adhesive on injection molded plastic bumps on the support face of the support element. As an alternative for attachment bonding technology or classical build up and connection technologies may be employed. The injection molded circuit substrate is however not only fitted with the sensor element but also receives the layout or artwork of the printed wiring, necessary for the function of the sensor, or, respectively, the electrical circuit resulting therefrom. Owing to the particular alignment of the Hall plate with a plate plane extending at a right angle to the longitudinal axis of the circuit substrate it is possible to ensure that in operation multiple switching is prevented and there is even the possibility of finding the sign of the magnetic field direction in conjunction with a permanently magnetic actuating element and accordingly to derive the direction of movement of the component bearing the actuating element. The particular alignment of the Hall plate furthermore permits optimum manufacture in connection with the MID technology with an extremely small accommodating space, more particularly since the arrangement of the printed wiring is extremely adaptable if the circuit structure is constituted by a structured or micromachined metallic layer applied to the support element.

Further advantageous developments of the invention are defined in the dependent claims.

The position sensor is preferably so designed that the rear side, opposite to the front end face, fitted with the sensor element, of the circuit substrate has an electrical lead extending from it, whose electrical conductors are in electrical contact with the printed wiring of the circuit substrate and by way of which the sensor signals are transmitted. Between front and the rear end region of the circuit substrate an attachment means may be provided, using which the position sensor may be secured so as to be detachably braced (in use) in an attachment slot.

The circuit substrate in the form of a MID component may bear not only the sensor-relevant circuit of the position sensor but also simultaneously serve as a support for attachment means serving for fixing the position sensor in place so that to this extent no separate housing components are required.

The printed wiring preferably extends at least partially in recesses in the support element, which are filled with a film material, which covers the printed wiring in a hermetically sealing manner.

Preferably, all electrical components of the position sensor are encapsulated in a casing material, which may be preferably a plastic material applied by injection molding. The casing material then performs the function of a housing and simultaneously passivation of the electrical regions.

If the filler material is made transparent to light the signals of integrated optical display means may be reliably visually detected from the outside. This means simple monitoring of the switched state of the position sensor.

Preferably, the support face for the sensor element is directly on the front end face of the support element and faces in the longitudinal direction of the circuit substrate.

Preferably the front end region of the support element is constituted by a T-like support section, which possesses a connecting neck extending in the longitudinal direction in the middle of the width and a transversely extending support board adjoining it. The support board defines the support face for the sensor element. The connecting neck may be employed to mount electronic components owing to its slim form.

The support element may be fitted with electronic components on the printed wiring which cooperate in evaluating the sensor signals. They may in particular constitute electronic evaluating circuitry. The latter is more particularly the case, when the sensor element is directly constituted by a Hall plate. As an alternative there is also the possibility however of providing an Hall chip as a sensor element, which contains both the Hall plate and also electronic evaluating circuitry.

It is also quite readily possible for the position sensor to be fitted with at least one further Hall sensor element, which may be utilized for the detection of the second field component of the magnetic field.

In the following the invention will be described in detail with reference to the accompanying drawings.

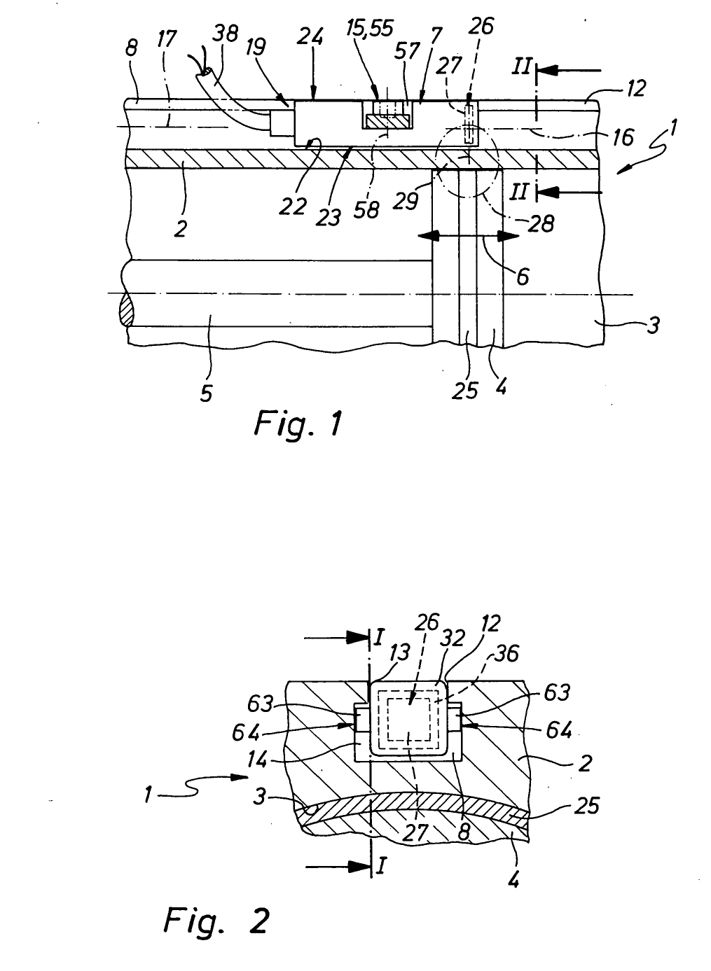

FIG. 1 shows in longitudinal section part of a fluid operated linear drive fitted with the position sensor in accordance with the invention, as seen on the section line I-I of FIG. 2.

FIG. 2 shows a cross section taken through the arrangement of FIG. 1 on the section line II-II.

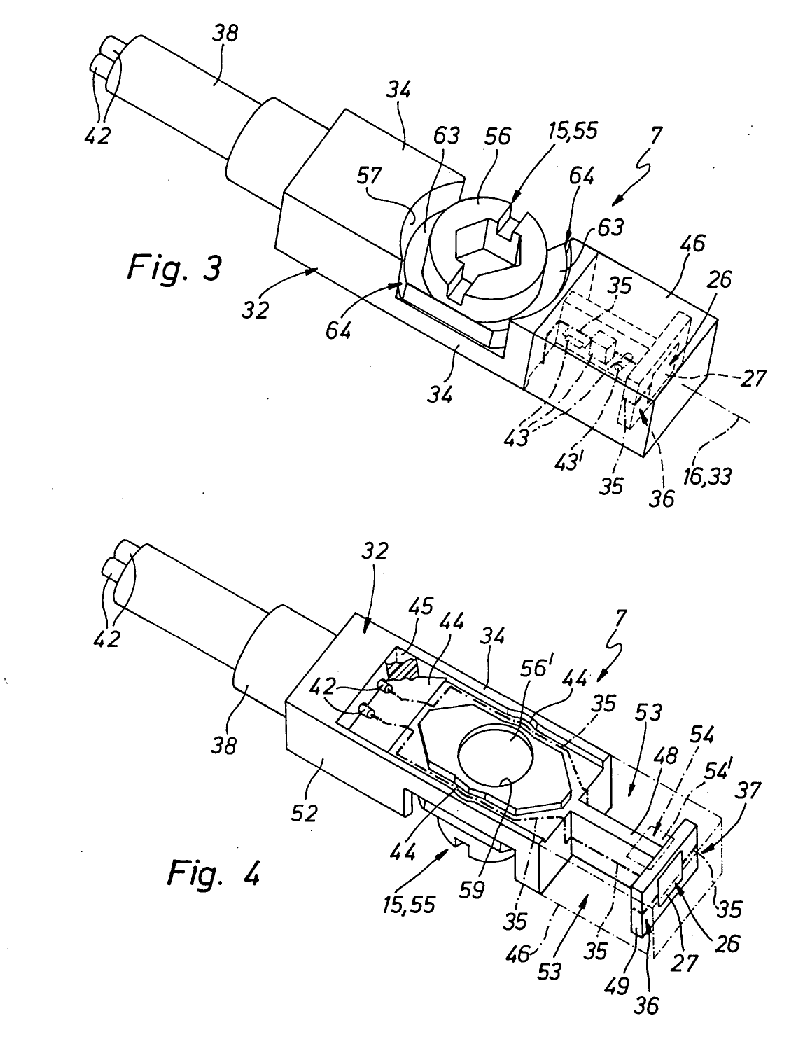

FIG. 3 is a separate view of the position sensor in perspective and as seen from above.

FIG. 4 shows the position sensor as seen from below, the casing material present not being indicated or only indicated in chained lines in order to render the individual components more readily apparent.

The FIGS. 1 and 2 show part of a fluid operated linear drive 1, as for example a pneumatic or hydraulic fluid power cylinder. It possesses an elongated housing 2, in which a piston space 3 is delimited, which receives a piston 4 running in the longitudinal direction. The piston 4 is for example connected with a force output part 5, constituted for example by a piston rod, which extends out from the housing 2 and renders possible output of force for the actuation of a component.

The linear movement 6, indicated by the double arrow, of the piston is due to suitable supply of fluid to the two piston space sections, partitioned by the piston.

For detecting the position of the piston 4 the linear drive 1 is fitted with at least one position sensor 7. Same is detachably secured in an attachment slot 8 at the outer periphery of the piston space 3 and cut in the outer face of the housing 2.

The attachment slot 8 in the working embodiment is a so-called T slot. Such slot possesses a neck 13 as a slot opening 12 which is adjoined by a wider base section 14 more particularly shaped rectangularly and extending in the depth direction of the attachment slot 8.

The position sensor 7 may be inserted through the slot opening 12 at any desired position in the attachment slot 8. The sensor 7 is provided with attachment means 15 which provide for a releasable, clamping attachment in the attachment slot 8. They are more particularly designed for bracing against the flanks of the attachment slot 8.

The position sensor 7 possesses an elongated and more particularly beam-like shape. In the condition inserted in the attachment slot its longitudinal axis 16 runs parallel to the longitudinal axis 17 of the attachment slot 8. As related to the state inserted in the attachment slot 8 the position sensor 7 has a front side aligned in the direction of the longitudinal axis 16 a rear side 19 aligned opposite to this, a bottom side 23 facing the floor 22 of the attachment slot 8 and a top side 24 facing opposite to the bottom side 23, such top side being more especially at the level of the slot opening 12.

The position sensor 7 is provided in order to detect a predetermined position of the piston 4. In this case it may be a question of an end position of the piston or an intermediate position occurring during the piston motion. The detection of a position takes place without physical contact being made and is on the basis of the cooperation of an actuating element 25 arranged on the piston 4 and a sensor element 26 arranged in the position sensor 7.

In the case of the position sensor 7 it is a question of a Hall sensor with compact overall dimensions. Its sensor element 26 comprises a Hall plate 27, which reacts to components of a magnetic field 28 indicated in chained lines, which extend through it at a right angle to its plane 29. The magnetic field 28 is produced by the actuating element 25, in the case of which it is preferably a question of a permanent magnet.

The principle of functioning is based on the so-called Hall effect. In this case the fact is relied on that in electrical conductors, which are located in a homogeneous magnetic field and in which an electric current is flowing, perpendicularly to the magnetic field, perpendicularly to the magnetic field and to the current a voltage differential will be produced, i.e. the so-called Hall voltage. In the case of the Hall sensor the function of the electrical conductor is assumed by a plate-like conductor element referred to as a Hall plate.

A substantial advantage of the position sensor 7 in accordance with the invention is due to the particular alignment of the Hall plate 27. It is so installed on the position sensor 7 that its plane 29 is perpendicular to the longitudinal axis 16 of the position sensor 7. In other words, the normal vector of the Hall plate 27 runs parallel to the longitudinal axis 16.

In conjunction with this alignment the drive voltage producing a flow of electrical current is applied to two mutually opposite edges of the Hall plate 27. The components of the magnetic field 28 extending through the Hall plate 27 perpendicularly to the plate plane 29, then give rise to the Hall voltage able to be tapped between the two other edges of the Hall plate 27, the sensor signal being derived from such voltage.

The advantage is in this respect that the characteristic of the Hall voltage has only one maximum, when the Hall plate 27 is pervaded by the magnetic field moving past. It is in this manner that multiple switching may be excluded. Furthermore, there is the possibility of detecting the sign of the field direction and accordingly the direction of motion of the piston 4.

At this point it is to be noted that the position sensor in accordance with the invention, while being particularly advantageous in conjunction with that fluid power systems, is more particularly suitable for fluid operated linear or other drives. Other fields of application are possible too, in which instead of the piston 4 the position of another moving component is to be detected.

A particularly significant role as regards the possibility of placing the Hall plate 27 with the indicated orientation while nevertheless ensuring compact sensor dimensions, is played by the design and structure of the position sensor 7. In this connection there is the provision that the position sensor possesses an elongated circuit substrate 32 in the form of a molded interconnect device (MID) which at least partly assumes the function of the sensor housing and simultaneously bears the electrical circuit necessary for the operation of the Hall sensor and the circuit components and furthermore the sensor element 26. The longitudinal axis 33 of the circuit substrate at the same time defines the longitudinal axis 16 of the position sensor 7.

The circuit substrate 32 comprises an elongated support element 34 of injection molded plastic material. It constitutes the supporting structure of the position sensor 7 and function simultaneously as a support or substrate for the above mentioned circuit and associated components.

On the surface of the support element 34 there extend several printed wiring parts 35 only indicated as an example and in chained lines, such printed wiring serving inter alia for making electrical contact with the position sensor 26 and, respectively, the Hall plate 27. The printed wiring 35 is constituted by a structured metal layer applied to the support element 34. Manufacture takes place for example with extensive metallization of the support element 34 previously produced by injection molding and structuring by electroplating treatment. It is particularly advantageous that MID technology renders possible the production of three-dimensional conductor artwork or layout which renders possible an optimum space saving arrangement of the conductors.

The sensor element 26 is applied to a support face 36 defined by the support element 34. The printed wiring may be formed as contact pads in this region which using flip chip technology rendering possible electrical contacting and simultaneously mechanical attachment in place of the sensor element 26. Other contacting measures are however possible too.

The sensor element 26 is so applied to the support face 36 that the plane 29 of the Hall plate 27 is perpendicular to the longitudinal axis 33 of the circuit substrate 32 and accordingly assumes the desired above mentioned alignment on installation of the position sensor 7 in the attachment slot 8.

The support face 36 is located at the front end side 37 of the support element 34. The desired alignment of the Hall plate may be attained in a particularly simple manner during the production of the sensor, if the support face 36 is already aligned in the longitudinal direction 33 of the circuit substrate 32, more particularly so that a normal to its surface is co-directional with the longitudinal axis 33 of the circuit substrate 32. In the working embodiment the support face 36 is directly on the front end side 37, aligned in the direction of the longitudinal axis 33, of the support element 34. The front region of the position sensor 7 may accordingly be termed the detection region.

For the supply of power and the transfer of the evaluation signals an electrical connection lead 38 is connected with the circuit substrate 32. This connection lead 38 extends in the working example from the rear side of the circuit substrate 32 so that the rear region of the circuit substrate 32 may be termed the connection region.

The electrical conductors 42 of the connection lead 38 make electrical contact on the circuit substrate 32 with the printed wiring 35 extending on it.

Accordingly the printed wiring 35 extends on the support element 34 between the detection region and the connection portion. Its configuration is so set during the production by MID technology as required that account is taken of other conditions, as for example a space saving arrangement of the electronic component 43 or as regards an optimum integration of the attachment means 15 for the attachment technology.

In the working embodiment the printed wiring 35 extends in FIG. 4 on its path between the sensor element 26 and the electrical conductors 42, ending in the connection region, at least partially in recesses 44 molded at the bottom side of support element 34 at least partially in the support element 34. These recesses 44 are filed with a filler material 45 only indicated in part, which covers over the printed wiring 35 and the contact regions for the electrical conductors 42, the material so connecting with the support element 34 in a bonding manner with or without adhesive that a hermetically sealed cover or capsule for the above mentioned components is produced.

Such a sealed capsule or encapsulation is however not only provided for the printed wiring 35 and the above mentioned contact regions for the electrical conductors 42 but also as regards the sensor element 26 and any possible electronic components 43 indicated in chained lines in FIG. 3. The electronic components 43 are preferably, just like the sensor element 26, arranged in the front detection region of the position sensor 7. Encapsulation takes place here preferably by having a casing body 46 later molded in place by injection molding, the material for the casing body 46 preferably being a material identical to the above mentioned filler material. During the manufacture of the position sensor 7 the filling of the recesses 44 and the molding on of the casing body 46 preferably takes place in a single injection molding operation.

Accordingly the casing body 46 assumes, together with the support element 34, the function of the sensor housing and simultaneously ensures passivation of the electrical regions.

The printed wiring 35 is fitted, to the extent necessary for the operation of the position sensor, in addition to the sensor element 26, with electronic components 43. If the sensor element 26 only consists of the Hall plate 27, the electronic components 43 may constitute evaluating electronic circuitry suitable for signal evaluation or processing. However there is furthermore the possibility of providing the evaluating electronic circuitry together with Hall plate directly in the sensor element 26 and of combining it in a Hall chip, something which facilitates the electrical fitting of the printed wiring 35 with components, because the number of the components to be mounted is reduced. The evaluating electronic circuitry may for example by a so-called ASIC.

The electronic components 43 contacted by the printed wiring 35 may also include optical display means 43′, as for instance at least one LED. The switched state of the position sensor 7 may be indicated visually thereby. In this respect it is preferable for the material of the casing body 46 to be transparent to light so that the light may radiate outward.

In the working embodiment there is a particularly advantageous design of the support element 34 on its end region forming the detection region. This front end region is formed by a T-like support section 47, which possesses a connecting neck 48 corresponding to the vertical section of the letter T and a support board 49 corresponding to the head part of the letter T.

The connecting neck 48 starts from a principal section 52, having the connection region and the attachment means 15, of the support element 34 and extends in the longitudinal direction to the fore, it being aligned with the middle of the width. It has plate-like, flat shape, its principal plane of extent being spanned by vectors, which extend in the longitudinal direction and in the height direction of the position sensor 7. The support board 49 extends perpendicularly thereto, its plane of extent being parallel to the that of the Hall plate 27 and the side, opposite to the connecting neck 48 and directed to the fore, of the support board 49 directly defining the support face 36.

Owing to this structure receiving recesses 53 in the support element 34 are provided which extend on either side of the connecting neck 48 axially between the support board 49 and the principal section 52, in which recesses electronic components in contact with the printed wiring 35 may be conveniently accommodated. More especially there is the possibility of employing the two oppositely directed large side faces of the connecting neck 48 for mounting the electronic components 43.

Should it be desired the support element 34 may be fitted with a further Hall sensor element 54 for the detection of the second field component of the magnetic field 28, the Hall plate 54′ thereof being orientated differently to the Hall plate 27 of the first sensor element 26 so far described. The alignment of the further Hall plate 54′ is preferably perpendicularly to the first Hall plate 26 so as to run athwart the direction of the position sensor 7 (indicated in chained lines in FIG. 4).

In the working embodiment the above mentioned attachment means 15 constitute a single attachment means 55 placed between the front and the rear end region of the circuit substrate 32. It is more particularly placed at the longitudinal middle of the circuit substrate 32. In the working embodiment it comprises a rotary member 56, that is seated in a receiving recess 57 open to the top side 24 and the two transversely aligned longitudinal sides, in the support element 34 and is able to be turned about an axis of rotation 58, extending in the vertical direction of the circuit substrate 32, in relation to the support element 34. In FIG. 4 the reader will see a cylindrical bearing spur 56′ of the rotary member 56, which starting at the receiving recess 57 fits in an adjoining bearing receiving means 59, arranged in a complementary manner, of the support element 34, so that the spur 56′ may turn.

At the periphery the rotary member 56 is provided with two diametrally opposite clamping projections 63. They may for example have an a radially orientated clamping face 64 which is eccentric in relation to the axis 58 of turning.

For the insertion or removal of the position sensor 7 the rotary member 58 is so aligned that the clamping projections 63 are aligned in the longitudinal direction of the position sensor 7 so that the rotary member 56 does not project laterally past the outer face of the circuit substrate 32 or only does so to a slight extent. After the insertion into the attachment slot 8 the rotary member 56 is turned until the clamping projections clamp against the flanks of the attachment slot 8 and the position sensor 7 accordingly is held reliably by a releasable bracing effect (FIG. 2).

It is also to be mentioned that the position sensor may be readily so designed that it permits recognition of the switching range (setup recognition) and furthermore provides for reliable detection of the field strength and the processing thereof as an analog signal and after all as a teachable sensor.

1. A position sensor designed in the form of a Hall sensor, comprising an elongated circuit substrate designed as a molded interconnect device (MID), which includes an elongated support element consisting of injection molded plastic material and having at a front end side thereof a support face which is so fitted with a sensor element including a Hall plate or constituted by a Hall plate that the plane of the Hall plate extends at a right angle to the longitudinal axis of the circuit substrate, the sensor element being electrically contacted by means of printed wiring constituted by a structured metal layer applied to the support element.

2. The position sensor as set forth in claim 1, further comprising an electrical lead extending from the rear side, opposite to the front end side, of the circuit substrate, electrical conductors of the lead being contacted by printed wiring of the circuit substrate.

3. The position sensor as set forth in claim 2, wherein the printed wiring extends on its path between the sensor element and the electrical conductors of the lead at least partially at the bottom side of the support element.

4. The position sensor as set forth in claim 1, wherein the printed wiring extends at least partially in recesses in the support element and is covered in a hermetically sealing fashion by filler material applied to the recess.

5. The position sensor as set forth in claim 1, wherein the support element is fitted with electronic components on the printed wiring.

6. The position sensor as set forth in claim 1, wherein the sensor element and the printed wiring and furthermore any electronic components provided on the support element are encapsulated in a casing body of plastic material, which is molded in position by injection molding on the support element.

7. The position sensor as set forth in claim 6, wherein the material of the casing body is transparent to light so that optical signals of encapsulated optical display means may emerge.

8. The position sensor as set forth in claim 1, wherein the support face for the sensor element is oriented in the longitudinal direction of the circuit substrate, a normal to its face being more especially co-directional with the longitudinal axis of the circuit substrate.

9. The position sensor as set forth in claim 8, wherein the support face is provided directly on the front end side of the support element.

10. The position sensor as set forth in claim 1, wherein the front end region of the support element is constituted by a T-like support section which, together with a connecting neck extending in the longitudinal direction in the middle and with an adjoining transversely extending support board, defines the support face.

11. The position sensor as set forth in claim 1, wherein the sensor element is a Hall chip provided with an evaluating electronic system, in addition to the Hall plate.

12. The position sensor as set forth in claim 1 further comprising an attachment means provided between the front and the rear end region of the circuit substrate for releasable clamping attachment of the position sensor in an attachment slot in another component.

13. The position sensor as set forth in claim 12, wherein the attachment means is placed on the circuit substrate in the longitudinal middle thereof.

14. The position sensor as set forth as set forth in claim 1, wherein the sensor is designed to be placed during use in such a fashion in an attachment slot in a component that its longitudinal axis extends parallel to the longitudinal axis of the attachment slot and possesses attachment means rendering possible a detachable clamping attachment in the attachment slot.

15. The position sensor as set forth in claim 1, wherein the circuit substrate at least partially constitutes the sensor housing.

16. The position sensor as set forth in claim 1, further comprising second Hall sensor element having a second Hall plate whose alignment is unlike that of the first Hall plate of the first sensor element.
